(19) United States
(12) Patent Application Publication
(10) Pub. No.: US 2017/0201191 A1
(43) Pub. Date: Jul. 13, 2017

(54) SEMICONDUCTOR DEVICE

(71) Applicant: National Tsing Hua University, Hsinchu City (TW)

(72) Inventor: Jyh-Ming Wu, Hsinchu County (TW)

(21) Appl. No.: 15/173,486

(22) Filed: Jun. 3, 2016

(30) Foreign Application Priority Data
Jan. 13, 2016 (TW) 105101002

(51) Int. Cl. H02N 1/00; H01L 29/772; H01L 29/423; H01L 29/45; H01L 29/417

(52) U.S. Cl. CPC H02N 1/00; H01L 29/45; H01L 29/41725; H01L 29/42316; H01L 29/772; H01L 29/20

(57) ABSTRACT

A semiconductor device is provided. The semiconductor device includes a substrate, a contact layer, and an active layer. The contact layer is located on the substrate. The contact layer and a movable object perform a relative motion. The active layer is located between the contact layer and the substrate.

### CROSS-REFERENCE TO RELATED APPLICATION

This application claims the priority benefit of Taiwan application serial no. 105101002, filed on Jan. 13, 2016. The entirety of the above-mentioned patent application is hereby incorporated by reference herein and made a part of this specification.

### BACKGROUND OF THE INVENTION

Field of the Invention

The invention relates to a semiconductor device, and particularly relates to an electrostatic induction semiconductor device.

Description of Related Art

The interaction between technology and human is based on the interface design wherein how to input and output messages being the most important function. Human senses are derived from five kinds of perception, namely, based on: sight, hearing, taste, smell and touch, wherein the touch sense is the most direct perception source but also the most difficult to imitate.

The current semiconductor devices usually need an applied voltage or an external power source so that the semiconductor device can be operated normally. Thereby, the manufacturing process of the semiconductor is more complicated and the application range thereof is limited. However, if the semiconductor device can self-generate power, then the semiconductor device can be operated without the applied voltage or the external power source, hence, the application range thereof can be extended.

### SUMMARY OF THE INVENTION

The invention provides a semiconductor device, which can self-generate power by generating an induced charge, such that the advantages of flexibility, transparency, and a thin structure can be achieved.

The invention provides a semiconductor device. The semiconductor device includes a substrate, a contact layer, and an active layer. The contact layer is located on the substrate. The contact layer and a movable object perform a relative motion. The active layer is located between the contact layer and the substrate.

According to an embodiment of the invention, the contact layer is a dielectric layer.

According to an embodiment of the invention, a material of the contact layer includes polyethylene oxide, silicon oxide, polydimethylsiloxane, polyimide, polyvinylidene fluoride (PVDF), titanium dioxide, tin dioxide, zinc diselenide, tin diselenide, vanadium dioxide, porous vanadium dioxide, PCBM ([6,6]-phenyl-C61-butyric acid methyl ester), PEDOT:PSS (poly(3,4-ethylenedioxythiophene) polystyrene sulfonate), or any organic and inorganic material with dielectric constant more than 1. Additionally, nylon, silcione gel, rubber, furs, etc are also included; however, the present invention is not limited thereto.

According to an embodiment of the invention, a thickness of the contact layer ranges from 10 nm to 20 mm.

According to an embodiment of the invention, a source and a drain located in the contact layer is further included.

According to an embodiment of the invention, the movable object and the contact layer have a relative potential difference therebetween.

According to an embodiment of the invention, a material of the active layer includes indium antimonide, gallium arsenide, indium phosphide, germanium silicide, silicon carbide, germanium, silicon, zinc oxide, titanium dioxide, tin dioxide, vanadium dioxide, vanadium pentoxide, molybdenum disulfide, tungsten diselenide, zinc diselenide, tin diselenide, tungsten disulfide, tungsten oxide, graphene, red phosphorus, black phosphorus, brown phosphorus, gallium nitride, PCBM ([6,6]-phenyl-C61-butyric acid methyl ester), graphite/P3HT (poly(3-hexylthiophene-2,5-diyl):PCBM, MEH-PPV (poly[2-methoxy-5-(2-ethylhexyloxy)-1,4-phenylenevinylene]), PEDOT:PS (polystyrene), Alq3 (tris(8-hydroxyquinolinato)aluminium, Al(C₉H₆NO)₃), fullerene, semiconductors from the III-V group or the II-VI group, or a combination thereof.

According to an embodiment of the invention, a distance d between the movable object and the contact layer ranges from 10 nm to 20 mm, and preferably ranges from 1 μm to 200 μm.

Based on the above, the semiconductor device of the invention can be manufactured into a semiconductor device having flexibility, transparency, and thin structure through the selection of materials. Additionally, the distance between the movable object and the contact layer of the semiconductor device of the invention can be controlled to generate a relative potential difference so as to induce a current or a voltage, and the induced current or voltage is enough to control the switch of the semiconductor device (the opening and the closing of the channel of the active layer). Thus, the gate source of the semiconductor device of the invention can be operated without the applied voltage or the external power source. Also, in the semiconductor device of the invention, the movable object is substituted for the gate electrode in the traditional semiconductor device structure. That is, when a finger is used as the movable object of the invention, the gate electrode component in the traditional semiconductor device structure can be omitted. Thus, a thickness of the overall semiconductor device can be reduced, and the thickness reduction advantage achieved.

In order to make the aforementioned features and advantages of the disclosure more comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a cross-sectional diagram of a semiconductor device according to an embodiment of the invention.

FIG. 2A to FIG. 2E are charge induction principle diagrams of a semiconductor device according to an embodiment of the invention.

FIG. 3A and FIG. 3B are electrical performance diagrams of the charge induction of the semiconductor device according to FIG. 2A to FIG. 2E.

FIG. 4A to FIG. 4E are charge induction principle diagrams of a semiconductor device according to another embodiment of the invention.

FIG. 5A and FIG. 5B are electrical performance diagrams of the charge induction of the semiconductor device according to FIG. 4A to FIG. 4E.

FIG. 6A and FIG. 6B are simulation diagrams of the potential difference between materials of a movable object and a contact layer according to different embodiments of the invention.

FIG. 7 is a circuit diagram according to an embodiment of the invention applied to a mesh-type electrode array.

### DESCRIPTION OF THE EMBODIMENTS

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

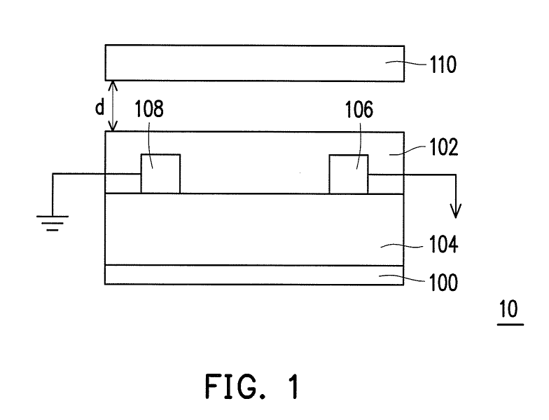

FIG. 1 is a cross-sectional diagram of a semiconductor device according to an embodiment of the invention.

Referring to FIG. 1, a semiconductor device 10 of the invention includes a substrate 100, a contact layer 102, and an active layer 104. A material of the substrate 100 includes a flexible material or a hard material, such as polyethylene terephthalate (PET), glass, silicon, stainless steel, aluminum oxide (Al₂O₃), aluminum, polyimide (PI), polyethylene naphthalate (PEN), polydimethylsiloxane (PDMS), copper, plastic, polyvinylidene fluoride (PVDF), glass fibers, or organic and inorganic mixture, etc; however, the present invention is not limited thereto. Additionally, the materials may be transparent or opaque materials. A thickness of the substrate 100 ranges from 1 μm to 10 mm, for example, and preferably from 100 μm to 1 mm.

The contact layer 102 is located on the substrate 100. The contact layer 102 may be, for example, a dielectric layer. For instance, a material of the contact layer 102 includes such as polyethylene oxide (PEO), silicon dioxide (SiO₂), polydimethylsiloxane, polyimide, polyvinylidene fluoride (PVDF), titanium dioxide, tin dioxide, zinc diselenide, tin diselenide, vanadium dioxide, porous vanadium dioxide, PCBM, PEDOT, PSS, or any organic and inorganic material with high dielectric constant (dielectric constant >1), etc; however, the present invention is not limited thereto. In a specific embodiment, when the material of the contact layer 102 is polyethylene oxide, since polyethylene oxide has a better quantum capacitance (4×10⁻³ F/m²), and polyethylene oxide is a transparent and flexible material, thereby the manufacturing process can be simplified and the subsequent application may be extended. However, the invention is not limited to the above materials. A thickness of the contact layer 102 ranges from 10 nm to 20 mm, for example, and preferably from 100 μm to 1 mm. In an embodiment, the contact layer 102 for example, further includes a source 106 and a drain 108 located therein. In an embodiment, for example, the drain 108 may be grounded.

The active layer 104 is located in between the contact layer 102 and the substrate 100. A material of the active layer 104 for example, may be an organic or inorganic n-type, p-type, or p-n type semiconductor material. Also, it may for example be an organic and inorganic hybrid semiconductor material. For instance, the material of the active layer 104 includes such as indium antimonide (InSb), gallium arsenide (GaAs), indium phosphide (InP), germanium silicide (SiGe), silicon carbide (SiC), gallium (Ga), silicon (Si), zinc oxide (ZnO), titanium dioxide (TiO₂), tin dioxide (SnO₂), vanadium dioxide (VO₂), vanadium pentoxide (V₂O₅), molybdenum diselenide (MoSe₂), iron disulfide (FeS₂), vanadium disulfide (VS₂), vanadium diselenide (VSe₂), chromium disulfide (CrS₂), chromium diselenide (CrSe₂), molybdenum disulfide (MoS₂), tungsten diselenide (WSe₂), tungsten disulfide (WS₂), tungsten oxide (WOₓ), graphene, red phosphorus, black phosphorus, brown phosphorus, gallium nitride, PCBM, graphite/P3HT:PCBM, MEH-PPV, PEDOT:PS, Alq3, fullerene, semiconductors in the III-V group or the II-VI group, or a combination thereof; however, the present invention is not limited thereto. Furthermore, it may be any ionic type or non-ionic type of semiconductor materials. The above material may be a wide bandgap or narrow bandgap semiconductor material, or may be a semiconductor material with a single interface or a p-n junction combination material. However, the invention is not limited thereto.

It should be noted that, the contact layer 102 and a movable object 110 may perform a relative motion. A distance d is generated by the relative motion in between the contact layer 102 and the movable object 110. The distance d for example, ranges from 10 nm to 20 mm, and preferably from 1 μm to 200 μm. A material of the movable object 110 is not specifically limited, as long as the material of the movable object 110 and the material of the contact layer 102 have a relative potential difference therebetween. For example, when the material of the contact layer 102 is polyethylene oxide, the material of the movable object 110 may be a material having higher negative electricity (also known as high electronegativity) compared to polyethylene oxide, which is a material with higher electron affinity, such as polytetrafluoroethylene (PTFE). On the contrary, the material of movable object 110 may be a material having higher positive electricity (also known as low electronegativity) compared to polyethylene oxide, which is a material with lower electron affinity, such as fingers or aluminum. However, the invention is not limited thereto, as long as the material of the movable object 110 and the material of the contact layer 102 have a relative potential difference therebetween.

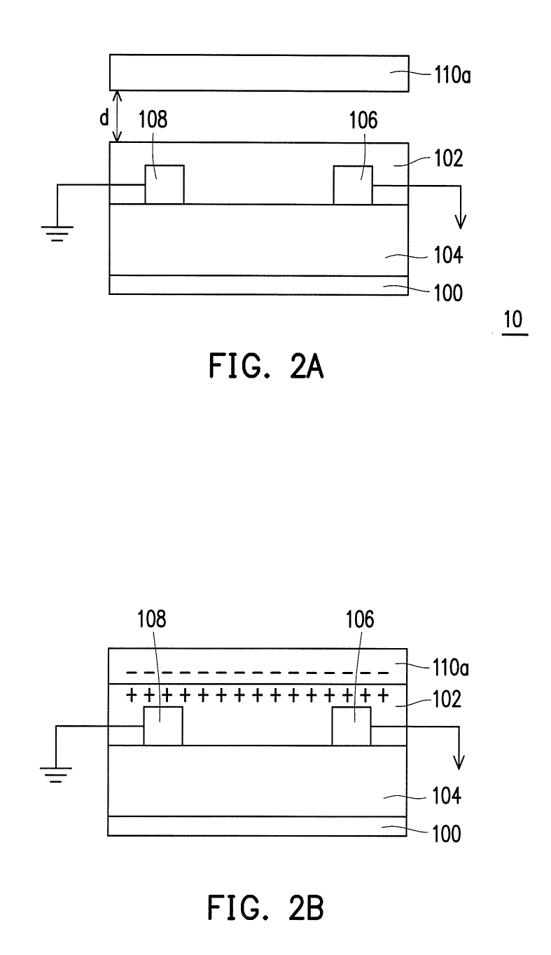

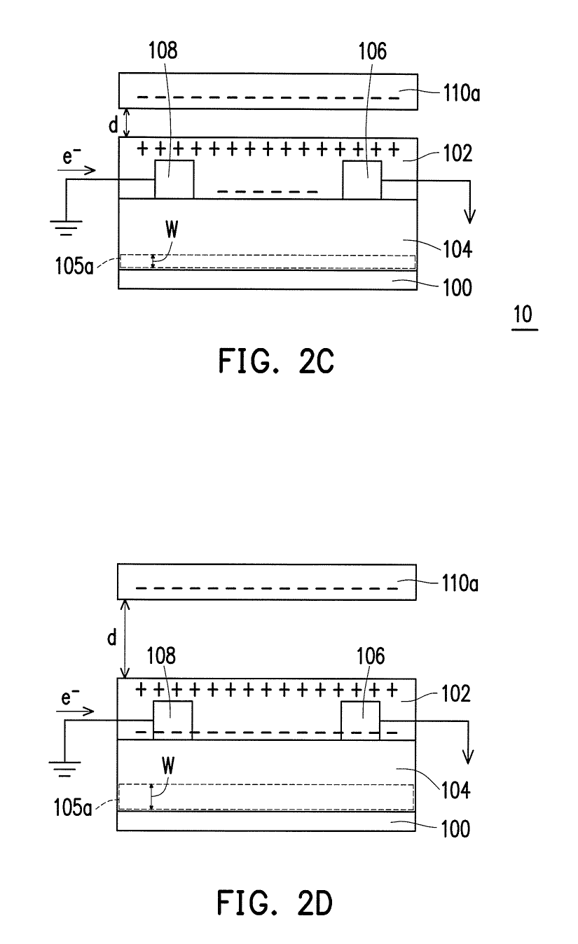

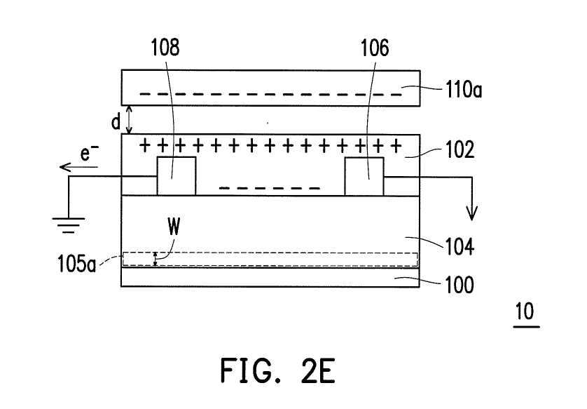

FIG. 2A to FIG. 2E are charge induction principle diagrams of a semiconductor device according to an embodiment of the invention.

The operation principle of the charge induction of the semiconductor device of the invention is illustrated by the cross-sectional diagrams of the semiconductor device from FIG. 2A to FIG. 2E.

In the embodiment, the operation principle of the charge induction is illustrated by an enhancement zone type charge induction. For instance, the material of the substrate 100 is for example polyethylene terephthalate, the material of the contact layer 102 is for example polyethylene oxide, and a material of a movable object 110a is for example polytetrafluoroethylene. At this time, the material of the movable object 110a has higher negative electricity compared to the contact layer 102. The material of the active layer 104 is for example indium antimonide. However, the invention is not limited thereto.

As shown in FIG. 2A, when the movable object 110a is not in contact with or close to the contact layer 102, the induced charge is not generated.

Next, as shown in FIG. 2B, the movable object 110a is in contact with the contact layer 102. Since the movable object 110a has higher negative electricity compared to the contact layer 102, that is the contact layer 102 has high positive electricity (low electronegativity) itself, therefore, when the contact layer 102 is in contact with the movable object 110a, the contact layer 102 with high positive electricity and the movable object 110a with high negative electricity are in electrical neutral equilibrium.

Subsequently, as shown in FIG. 2C, the movable object 110a is slowly moved away from the contact layer 102. Since the surface of the contact layer 102 is still in a positive charge state, in order to reach electrostatic equilibrium, electrons are imported from the grounded drain 108 to maintain electrical neutrality, as such, the electron density of the active layer 104 will be increased to generate an enhancement zone 105a, wherein the enhancement zone 105a has a width w.

Next, as shown in FIG. 2D, when the distance d between the movable object 110a and the contact layer 102 continues to increase, the electron density may gradually achieve the maximum value, and the width w of the enhancement zone 105a may also gradually increase, as a result, the current flowing through the source 106 will also increase. When the electrostatic equilibrium is achieved, the charge equilibrium is in the electrical neutral state. That is, the current does not further increase and a maximum value of the enhancement zone 105a is achieved.

Subsequently, as shown in FIG. 2E, the movable object 110a is once again moved close to the contact layer 102. That is, the distance d between the movable object 110a and the contact layer 102 decreases, and electrons start flowing from the drain back to the ground. At this time, the electron density decreases, such that the width w of the enhancement zone 105a gradually decreases until returning to the original state.

It should be noted that, in the process of performing a relative motion between the movable object 110a and the contact layer 102, the current generated due to the electrostatic equilibrium is sufficient to achieve the control over the switching of the semiconductor device. That is, the gate of the semiconductor device does not need to be controlled by an external current. Additionally, the movable object 110a is located outside and independent from the semiconductor device, therefore, a circuit connection with the main body of the semiconductor device is not necessary. As such, the device design and the manufacturing process, and the cost thereof can be simplified effectively.

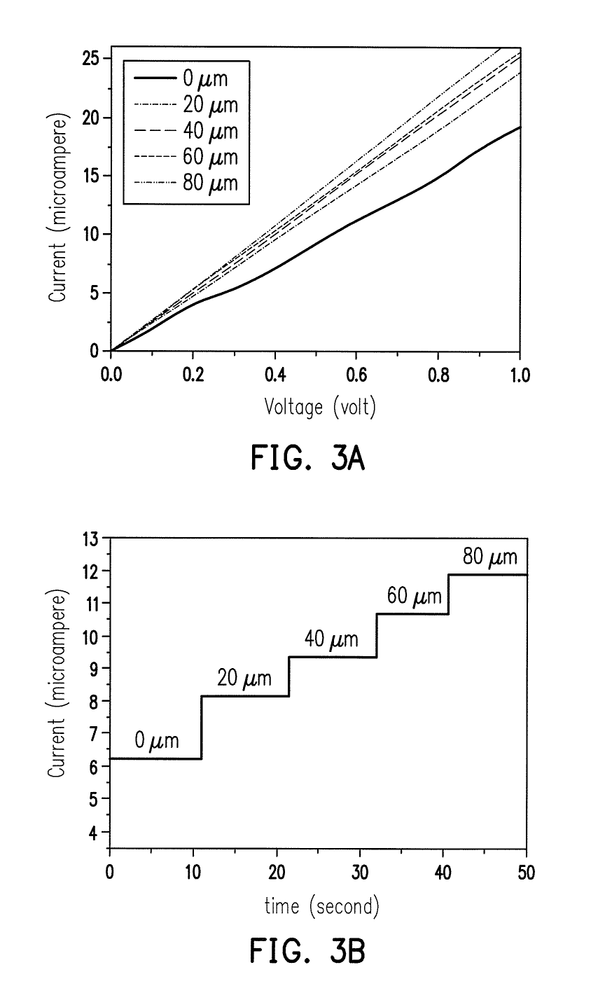

FIG. 3A and FIG. 3B are electrical performance diagrams of the charge induction of the semiconductor device according to FIG. 2A to FIG. 2E.

Referring to the results shown in FIG. 3A, from a position where the movable object 110a is in contact with the contact layer 102 to a position where the movable object 110a is away from the contact layer 102, the distance d gradually increases, and the amount of current also gradually increases. Additionally, from the results shown in FIG. 3B, it can be calculated that, when the bias voltage of the source 106 is fixed at 1 V, during the process of gradually moving the movable object 110a from a position where it is in contact with the contact layer 102 (d=0 μm) to a position where the movable object 110a is away from the contact layer 102 (d=80 μm), the amount of current increases from about 6 μA to 12 μA, that is, approximately a 2-fold increase is observed.

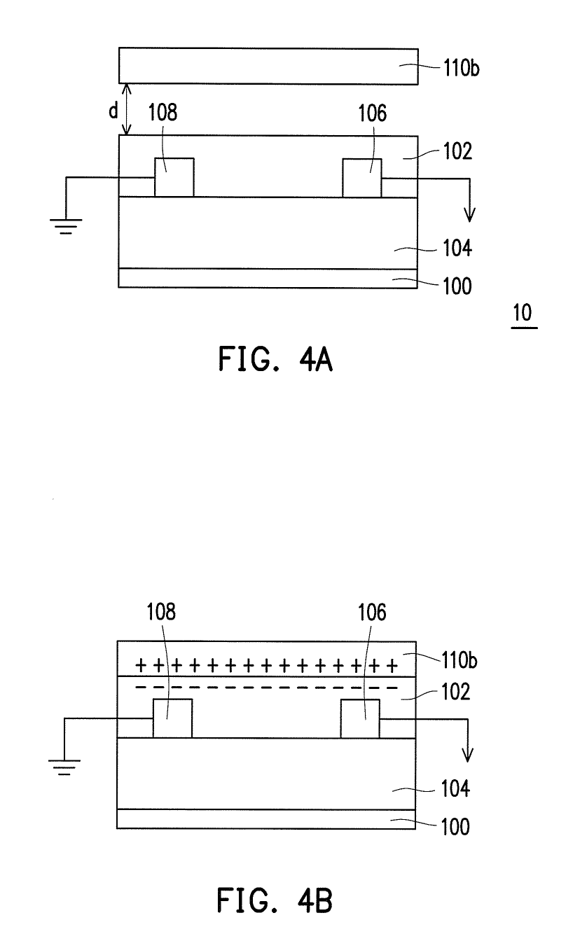

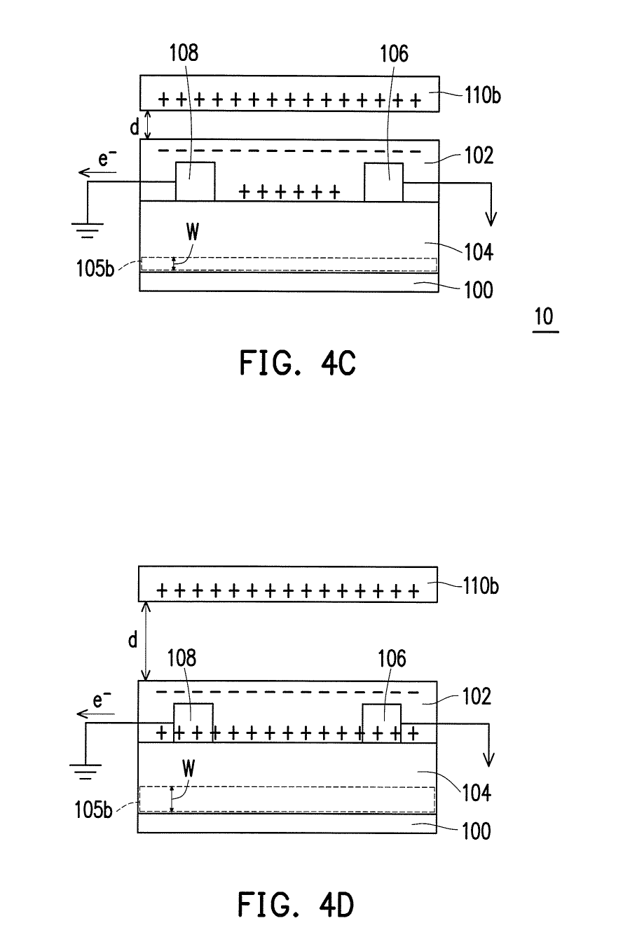

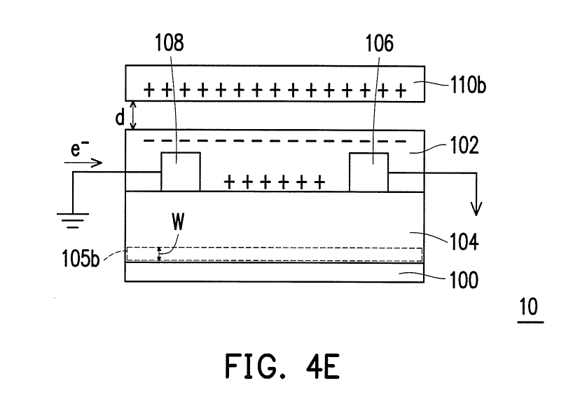

FIG. 4A to FIG. 4E are charge induction principle diagrams of a semiconductor device according to another embodiment of the invention.

In the embodiment, the operation principle of the charge induction is illustrated by a depletion zone type charge induction, which is contrary to the operation principle of the enhancement zone type charge induction described above. Particularly, the difference compared to the enhancement zone type charge induction is that, a movable object 110b is a material having higher positive electricity compared to the contact layer 102. For instance, the material of the contact layer 102 is for example polyethylene oxide, and a material of the movable object 110b is such as fingers, aluminum, silicon dioxide, porous silicon dioxide, or nylon. However, the invention is not limited thereto.

As shown in FIG. 4A, when the movable object 110b is not in contact with or close to the contact layer 102, the induced charge is not generated. Next, as shown in FIG. 4B, the movable object 110b is in contact with the contact layer 102. Since the movable object 110b has higher positive electricity (or low electronegativity) compared to the contact layer 102, the movable object 110b has positive charge itself while the contact layer 102 has higher negative electricity (or low electronegativity). Thus, when the movable object 110b with high positive electricity and the contact layer 102 with high negative electricity are in contact with each other, then an electrical neutral equilibrium is achieved. Subsequently, as shown in FIG. 4C, the movable object 110b is slowly moved away from the contact layer 102. Since the surface of the contact layer 102 is still in a negative charge state, in order to achieve electrostatic equilibrium, electrons are exported from the grounded drain 108 to decrease the electron density of the active layer 104, wherein a depletion zone 105b is generated. Next, as shown in FIG. 4D, when the distance d between the movable object 110b and the contact layer 102 continues to increase, the width w of the depletion zone 105b also gradually increase, as a result, the current flowing through the source 106 is reduced until the electrostatic equilibrium is achieved. Subsequently, as shown in FIG. 4E, the movable object 110b is once again moved close to the contact layer 102. That is, the distance d between the movable object 110b and the contact layer 102 decreases, and electrons flow from the ground back to the drain 108 to neutralize the positive charge originally existing in the active layer 104. As such, the current of the contact layer 102 starts to increase until returning to the original state.

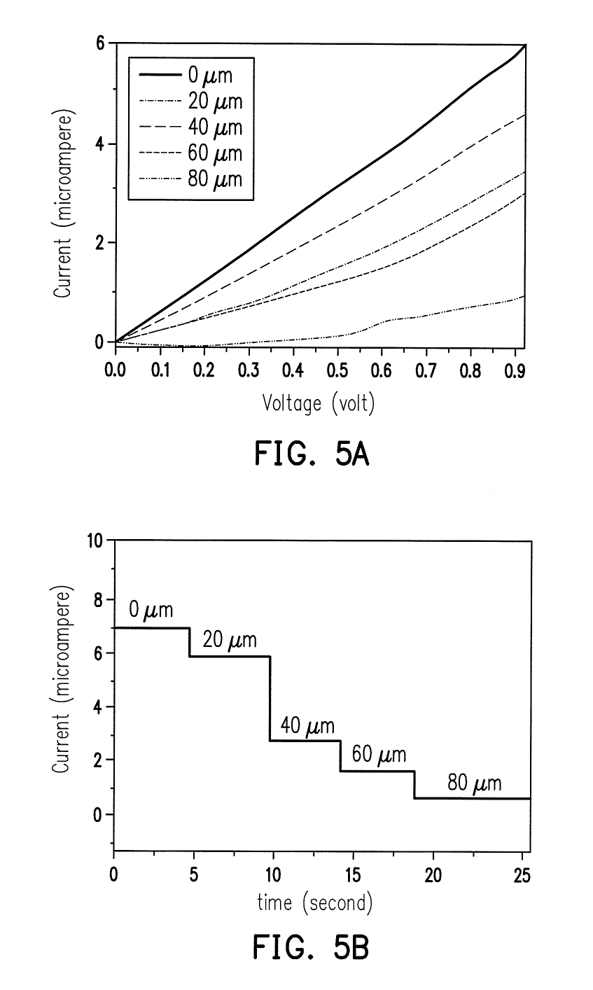

FIG. 5A and FIG. 5B are electrical performance diagrams of the charge induction of the semiconductor device according to FIG. 4A to FIG. 4E.

Referring to the results shown in FIG. 5A, from a position where the movable object 110b is in contact with the contact layer 102 to a position where the movable object 110b is away from the contact layer 102, the amount of current decreases while the distance d between the movable object 110b and the contact layer 102 increases. Additionally, from the results shown in FIG. 5B, it can be calculated that, when the bias voltage of the source 106 is fixed at 1 V, during the process of gradually moving the movable object 110b from a position where it is in contact with the contact layer 102 (d=0 μm) to a position where the movable object 110b is away from the contact layer 102 (d=80 μm), the amount of current decreases from about 7 μA to 1.5 μA, that is, approximately a 5-fold decrease is observed.

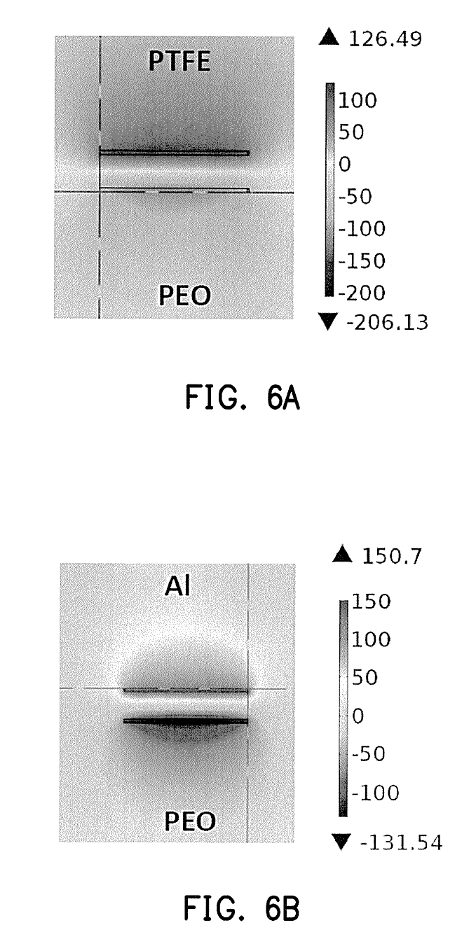

FIG. 6A and FIG. 6B are simulation diagrams of the potential difference between materials of a movable object and a contact layer according to different embodiments of the invention.

According to the simulation diagrams of the potential difference of FIG. 6A, it can be known that polytetrafluoroethylene has higher negative electricity compared to polyethylene oxide, wherein an output potential of +126V to −206V can be achieved based on the theoretical calculation. According to the simulation diagrams of the potential difference in FIG. 6B, it can be known that aluminum has higher positive electricity compared to polyethylene oxide, wherein an output potential of +151V to −132V can be achieved based on the theoretical calculation. From the simulation diagrams of the potential difference, it can be known that the movable object and the contact layer of the invention can be selected from materials having different charged electricity. That is, the self-generated power of the invention can be performed by the current or the voltage generated from the difference between the gain or loss of electrons based on the materials. Additionally, the materials of the movable object and the contact layer may for example, be selected from the combination of polytetrafluoroethylene with aluminum, or the surface roughness and the porosity of the structure of polytetrafluoroethylene and aluminum may be adjusted to increase the positive charge of aluminum or to increase the negative charge of polytetrafluoroethylene, so as to achieve a higher potential difference effect. However, the invention is not limited thereto.

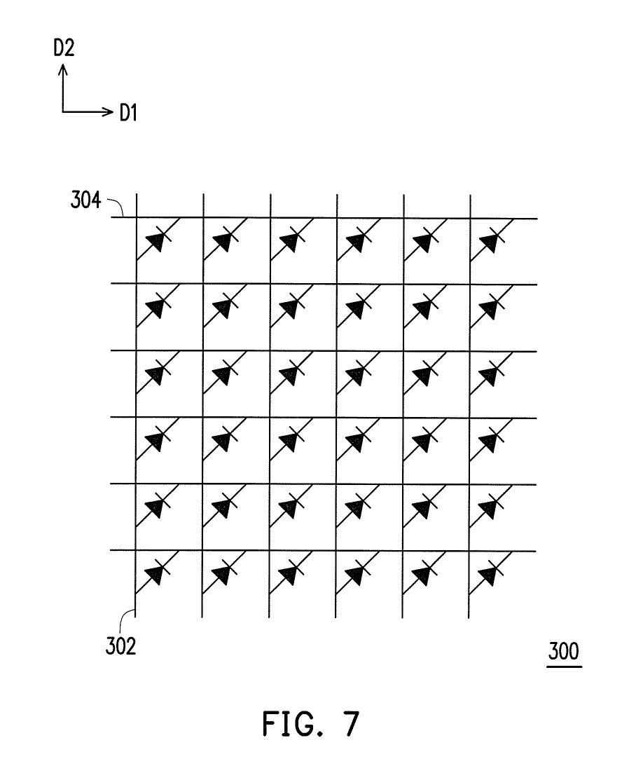

FIG. 7 is a circuit diagram according to an embodiment of the invention applied to a mesh-type electrode array.

As shown in FIG. 7, the semiconductor device of the invention can be applied to the design of a mesh-type electrode array 300. A plurality of first electrodes 302 are arranged along a first direction D1 and extended along a second direction D2, and a plurality of second electrodes 304 are arranged along the second direction D2 and extended along the first direction D1. The semiconductor device of the invention is provided respectively at the junction between each first electrode 302 and each second electrode 304 so as to be electrically connected thereto. Furthermore, an electric field effect may be generated between the gate and the contact layer by the potential difference obtained through the contact friction between the contact layer and the movable object. The electric field effect can be used to control the channel current in between the drain and the source of the active layer by the above-mentioned enhancement-type and depletion-type module. Furthermore, the semiconductor device can be formed as an array-control/touch circuit for induction position, such that the strength of the control signal is determined and an electrical signal is processed thereby.

In an embodiment, the mesh-type electrode array may for example include a plurality of the semiconductor devices 10 of the present invention. As in the principle of charge induction mentioned above, by controlling the distance between the movable object and the contact layer, the switching of the semiconductor device 10 at any position can be controlled.

It should be noted that, the channel switch of the semiconductor device of the invention can be controlled without other external power sources, therefore, the advantages where the gate manufacturing process may be simplified and a thin structure (less than 1 mm) may be achieved.

Additionally, in the semiconductor device of the present invention, the material of the contact layer and the material of the movable object are not specifically limited, as long as both of the materials have a relative potential difference therebetween. Except for the materials listed above, the materials of the movable object and the contact layer may optionally be a combination of two materials selected from the materials listed below. That is, the two materials selected will have a relative potential difference therebetween. The following materials having electricity from positive to negative listed in sequence are such as, skin, glass, nylon, wool, lead, cotton, aluminum, paper, steel, gelatin, nickel and copper, gold and platinum, natural rubber, sulfur, acetate, polyester, celluloid, urethane, polyethylene, vinyl, silicon, and teflon. However, the invention is not limited thereto.

The semiconductor device of the invention can be applied to keyboards, pulse sensors, force sensors, displacement detectors, speed sensors, touch panels, strain sensors, game joysticks, game keyboards, and other related applications. However, the invention is not limited thereto.

In summary, the semiconductor device of the invention can be manufactured into a semiconductor device having flexibility, transparency, and thin structure by the selection of suitable materials. Additionally, the distance between the movable object and the contact layer of the semiconductor device of the invention can be controlled to generate a relative potential difference so as to induce a current or a voltage. The generated induced current or voltage is enough to control the switch of the semiconductor device (the opening and the closing of the channel of the active layer). Therefore, the semiconductor device of the invention can be operated without an applied voltage or an external power source. Also, in the semiconductor device of the invention, the movable object is substituted for the gate electrode in the traditional semiconductor device structure. That is, when a finger is used as the movable object of the invention, the gate electrode component in the traditional semiconductor device structure can be omitted. Thus, a thickness of the overall semiconductor device can be reduced, and the thickness reduction advantage may be achieved.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

1. A semiconductor device, comprising:
a substrate;
a contact layer located on the substrate, wherein the contact layer is a dielectric layer, the contact layer and a movable object perform a relative motion so that the movable object and the contact layer have a relative potential difference therebetween, and an electric field effect is generated by the relative potential difference obtained through contact friction between the contact layer and the movable object;
a source and a drain located in the contact layer, and
an active layer located between the contact layer and the substrate.

2. (canceled)

3. The semiconductor device according to claim 1, wherein a material of the contact layer comprises polyethylene oxide, silicon oxide, polyimide, polyvinylidene fluoride, silicon dioxide, titanium dioxide, tin dioxide, zinc diselenide, tin diselenide, vanadium dioxide, porous vanadium dioxide, PCBM, PEDOT, PSS, or any organic and inorganic material with dielectric constant more than 1, and a combination thereof.

4. The semiconductor device according to claim 1, wherein a thickness of the contact layer ranges from 10 nm to 20 mm.

5-6. (canceled)

7. The semiconductor device according to claim 1, wherein a material of the active layer comprises indium antimonide, gallium arsenide, indium phosphide, germanium silicide, silicon carbide, germanium, silicon, zinc oxide, titanium dioxide, tin dioxide, vanadium dioxide, vanadium pentoxide, molybdenum disulfide, tungsten diselenide, zinc diselenide, tin diselenide, tungsten disulfide, tungsten oxide, molybdenum diselenide, iron disulfide, vanadium disulfide, vanadium diselenide, chromium disulfide, chromium diselenide, graphene, red phosphorus, black phosphorus, brown phosphorus, gallium nitride, PCBM, graphite/P3HT:PCBM, MEH-PPV, PEDOT:PS, Alq3, fullerene, semiconductors from the III-V group or the II-VI group, or a combination thereof.

8. The semiconductor device according to claim 1, wherein a distance d between the movable object and the contact layer ranges from 10 nm to 20 mm.
